(19) United States
(12) Patent Application Publication
(10) Pub. No.: US 2014/0060575 A1
(43) Pub. Date: Mar. 6, 2014

(54) SUBSTRATE TREATING METHOD

(71) Applicant: SEMES CO. LTD, Chungcheongnam-do (KR)

(72) Inventors: Kang Suk Lee, Chungcheongnam-do (KR); Jae Myoung Lee, Chungcheongnam-do (KR); Bok Kyu Lee, Chungcheongnam-do (KR); Yong Hee Lee, Chungcheongbuk-do (KR); Jin Bok Lee, Chungcheongnam-do (KR)

(73) Assignee: SEMES CO. LTD, Chungcheongnam-do (KR)

(21) Appl. No.: 14/012,523

(22) Filed: Aug. 28, 2013

(30) Foreign Application Priority Data
Aug. 31, 2012 (KR) 10-2012-0096776
Dec. 28, 2012 (KR) 10-2012-0156312

(51) Int. Cl. H01L 21/02

(52) U.S. Cl. CPC H01L 21/02057
USPC 134/4

(57) ABSTRACT

Provided is a substrate treating method. The substrate treating method may include treating a substrate by using a chemical solution; rinsing the substrate by using pure water after treating the substrate by using the chemical solution; and treating the substrate by using an organic solvent, wherein the substrate treating method further includes coating the substrate with a hydrophobic membrane between the treating of the chemical solution and the treating of the organic solvent.

### CROSS-REFERENCE TO RELATED APPLICATIONS

This U.S. non-provisional patent application claims priority under 35 U.S.C. §119 of Korean Patent Application Nos. 10-2012-0096776, filed on Aug. 31, 2012, and 10-2012-0156312, filed on Dec. 28, 2012, the entire contents of which are hereby incorporated by reference.

### BACKGROUND OF THE INVENTION

The present invention disclosed herein relates to a method for manufacturing a semiconductor substrate, and more particularly, to a substrate treating method.

In general, semiconductor devices are manufactured by performing various processes such as a photo process, an etching process, an ion implantation process, and a deposition process on substrates such as silicon wafers.

Also, a cleaning process for removing various contaminants attached to the substrates is performed while each of the processes is performed. The cleaning process includes a chemical treatment process for removing the contaminants attached to the substrates by using chemicals, a wet cleaning process for removing the chemicals remaining on the substrates by using pure water, and a drying process for drying the pure water remaining on surfaces of the substrates by supplying a dry fluid.

In the past, the drying process is performed by supplying a heated nitrogen gas onto the substrate on which the pure water remains. However, as a line width of each of patterns formed on a substrate decreases, and an aspect ratio of each of the patterns increases, it may difficult to remove the pure water existing between the patterns. In recent, a liquid organic solvent such as isopropyl alcohol having volatility greater than and surface tension less than that of the pure water may be substituted for the pure water, and then, the heated nitrogen gas may be supplied to dry the substrate.

### SUMMARY OF THE INVENTION

The present invention provides a substrate treating method which is capable of improving drying efficiency on the substrate.

The present invention also provides a substrate treating method preventing a pattern on a substrate from leaning during a substrate treatment process.

The feature of the present invention is not limited to the aforesaid, but other features not described herein will be clearly understood by those skilled in the art from this specification and the accompanying drawings.

Embodiments of the present invention provide substrate treating methods including: treating a substrate by using a chemical solution; rinsing the substrate by using pure water after treating the substrate by using the chemical solution; and treating the substrate by using an organic solvent, wherein the substrate treating method further includes coating the substrate with a hydrophobic membrane between the treating of the chemical solution and the treating of the organic solvent.

In some embodiments, the coating of the substrate with the hydrophobic membrane may be performed after the rinsing of the substrate.

In other embodiments, the substrate treating methods may further include supplying the organic solvent onto the substrate to substitute the pure water on the substrate by the organic solvent between the rinsing of the substrate and the coating of the substrate by using the hydrophobic membrane.

In still other embodiments, the organic solvent may include isopropyl alcohol (IPA).

In even other embodiments, the coating of the substrate by using the hydrophobic membrane may include providing a water-soluble coating solution containing a siloxane-based hydrophobic compound, which reacts with silicon (Si) on a surface of a pattern on the substrate, onto the substrate.

In yet other embodiments, the coating of the substrate by using the hydrophobic membrane may include providing an organic coating solution in which a siloxane-based hydrophobic compound reacting with silicon (Si) on the surface of the pattern on the substrate is mixed with the organic solvent onto the substrate.

In further embodiments, the substrate treating methods may further include removing the hydrophobic membrane after drying the substrate.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a plan view of a substrate treating apparatus according to an embodiment;

FIG. 2 is a cross-sectional view illustrating a substrate cleaning apparatus of FIG. 1 according to an embodiment;

FIG. 3 is a flowchart illustrating a substrate treating method by using the substrate treating apparatus of FIG. 1; and

FIG. 4 is a flowchart illustrating a substrate treating method by using the substrate treating apparatus of FIG. 1.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of the elements are exaggerated for clarity.

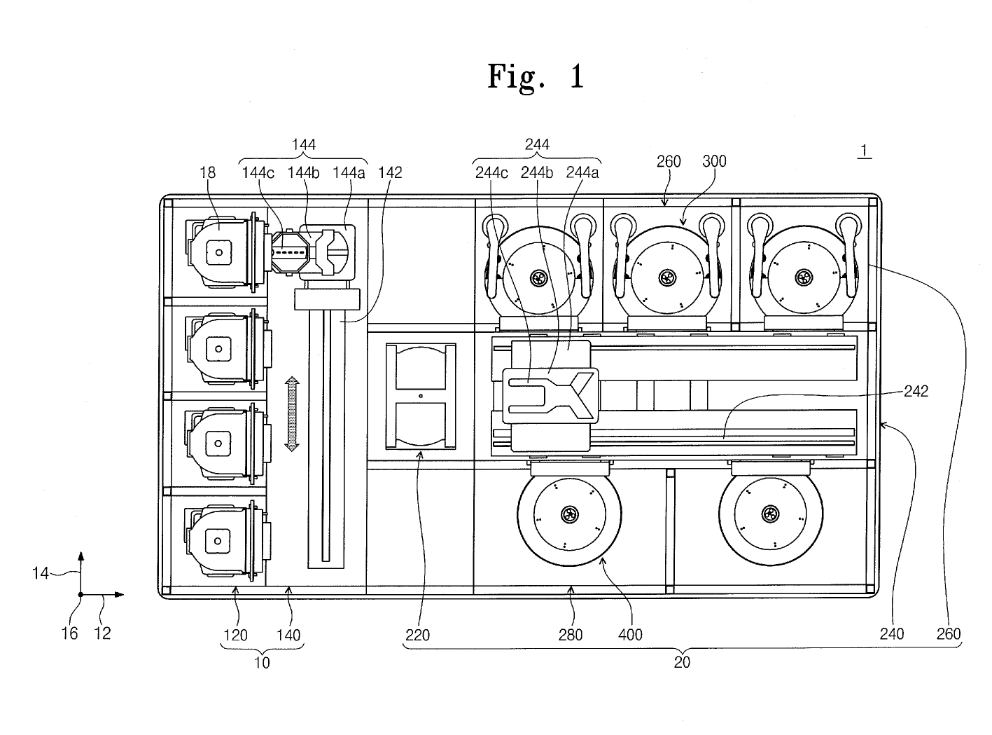

FIG. 1 is a plan view of a substrate treating apparatus according to an embodiment.

Referring to FIG. 1, a substrate treating apparatus 1 includes an index module 10 and a process treatment module 20. The index module 10 includes a load port 120 and a transfer frame 140. The load port 120, the transfer frame 140, and the process treatment module 20 are successively disposed in a line. Hereinafter, a direction in which the load port 120, the transfer frame 140, and the process treatment module 20 are arranged is referred to as a first direction 12. Also, when viewed from an upper side, a direction perpendicular to the first direction 12 is referred to as a second direction 14, and a direction perpendicular to a plane parallel to the first and second directions 12 and 14 is referred to as a third direction 16.

A carrier 18 in which a substrate is accommodated is seated on the load port 140. The load port 120 is provided in plurality. The plurality of load ports 120 are arranged in a line along the second direction 14. The number of load ports 120 may increase or decrease according to process efficiency and foot print conditions of the process treatment module 20. A plurality of slots for accommodating substrates in a state where the substrates are disposed parallel to the ground are defined in the carrier 18. A front opening unified pod (FOUP) may be used as the carrier 18.

The process treatment module 20 includes a transfer chamber 240, a buffer unit 220, a first process chamber 260, and a second process chamber 280. The transfer chamber 240 has a length direction parallel to the first direction 12. The first process chamber 260 and the second process chamber 280 are disposed on both sides of the transfer chamber 240, respectively. The first and second process chambers 260 and 280 may be symmetrical to each other with respect to the transfer chamber 240 on one side or the other side of the transfer chamber 240. A plurality of first process chambers 260 are disposed on the one side of the transfer chamber 240. Some of the first process chambers 260 are disposed along a length direction of the transfer chamber 240. Also, Some of the first process chambers 260 are laminated on each other. That is, the first process chambers 260 may be disposed in an A×B array on the one side of the transfer chamber 240. Here, the reference symbol “A” represents the number of process chambers 260 disposed in a line along the first direction 12, and the reference symbol “B” represents the number of process chambers 260 disposed in a line along the second direction 14. When four or six first process chambers 260 are disposed on the one side of the transfer chamber 240, the first process chambers 260 may be disposed in a 2×2 or 3×2 array. The number of first process chamber 260 may increase or decrease. Also, like the first process chambers 260, the second process chambers 280 may be disposed in an M×N (where each of M and N is a natural number greater than or equal to 1). Here, the natural numbers M and N may be equal to the numbers A and B of process chambers, respectively. Alternatively, all of the first and second process chambers 260 and 280 may be disposed on the only one side of the transfer chamber 240. Alternatively, the first and second process chambers 260 and 280 may be respectively disposed on the one side and the other side of the transfer chamber 240 in a single layer structure. Selectively, the first and second process chambers 260 and 280 may be laminated on each other on the one side or the other side of the transfer chamber 240. Also, the first and the second process chambers 260 and 280 may be arranged at various positions.

The buffer unit 220 is disposed between the transfer frame 140 and the transfer chamber 240. The buffer unit 220 provides a space in which substrates stay before the substrates are carried between the process chamber 260 and the carrier 18. The buffer unit 220 includes a slot in which a substrate is placed therein. The slot may be provided in plurality, and the plurality of slots may be spaced apart from each other along the third direction 16. A surface of the buffer unit 220 facing the transfer frame 140 and a surface of the buffer unit 220 facing the transfer chamber 240 may be opened.

The transfer frame 140 carries substrates between the carrier 18 seated on the load port 120 and the buffer unit 220. An index rail 142 and an index robot 144 are disposed on the transfer frame 140. The index rail 142 has a length direction parallel to the second direction 14. The index robot 144 is disposed on the index rail 142 to linearly move in the second direction 14 along the index rail 142. The index robot 144 includes a base 144a, a main body 144b, and an index arm 144c. The base 144a is disposed movable along the index rail 142. The main body 144b is coupled to the base 144a. The main body 144b is disposed movable along the third direction 16 on the base 144a. Also, the main body 144b is rotatably disposed on the base 144a. The index arm 144c is coupled to the main body 144b. Also, the index arm 144c may move in forward and backward directions with respect to the main body 144b. A plurality of index arms are provided so that the index arms are individually driven with respect to each other. The index arms 144c may be laminated in a state where the index arms 144c are spaced apart from each other along the third direction 16. Some of the index arms 144c may be used for carrying substrates into the carrier 18 from the process treatment module 20, and some of the other index arms 144c may be used for carrying substrates into the process treatment module 20 from the carrier 18. Thus, it may prevent particles generated from the substrates to be treated while the index robot 144 loads and unloads substrates from being attached to the treated substrates.

The transfer chamber 240 carries substrates between the buffer unit 240 and the process chamber 260 and between the process chambers 260. A guide rail 242 and a main robot 500 are disposed in the transfer chamber 240. The guide rail 242 has a length direction parallel to the first direction 12. The guide rail 242 has a length direction parallel to the first direction 12. The main robot 500 is disposed on the guide rail 242 to linearly move in the first direction 12 along the guide rail 242. The main robot 500 includes a base 530, a main body 520, and a main arm 510. The base 530 is disposed movable along the guide rail 242. The main body 520 is coupled to the base 530. The main body 520 is disposed movable along the third direction 16 on the base 530. Also, the main body 520 is rotatably disposed on the base 530. The main arm 510 is coupled to the main body 520. Also, the main arm 510 may move in forward and backward directions with respect to the main body 520. The main arm 510 may be provided in plurality. The plurality of main arms 510 may be individually driven with respect to each other. The main arms 510 may be laminated on each other in a state where the main arms 510 are spaced apart from each other along the third direction 16.

Substrate cleaning apparatuses 300 for performing a cleaning process on substrates is disposed within the process chambers 260, respectively. The substrate cleaning apparatuses 300 may have different structures according to a kind of cleaning processes to be performed. Alternatively, the substrate cleaning apparatuses 300 respectively disposed within the process chambers 260 may have the same structure. Selectively, the process chambers 260 may be classified into a plurality of groups. The substrate cleaning apparatuses 300 within the process chambers 260 belonging to the same group may be the same structure. On the other hand, the substrate cleaning apparatuses 400 within the process chambers 280 belonging to the groups different from each other may have structures different from each other. For example, when the process chambers 260 are divided into two groups, the process chambers 260 of a first group may be disposed on one side of the transfer chamber 240 and the process chambers 280 of a second group may be disposed on the other side of the transfer chamber 240. Alternatively, the process chambers 260 of the first group may be disposed on a lower floor, and the process chambers 280 of the second group may be disposed on upper floors on both sides of the transfer chamber 240. The process chamber 260 of the first group and the process chamber 280 of the second group may be distinguished from each other according to a kind of chemicals and a kind of cleaning methods. On the other hand, the process chamber 260 of the first group and the process chambers 280 of the second group may be provided to successively perform processes on one substrate W.

Hereinafter, an example of a substrate cleaning apparatus for cleaning a substrate by using a treating solution will be described.

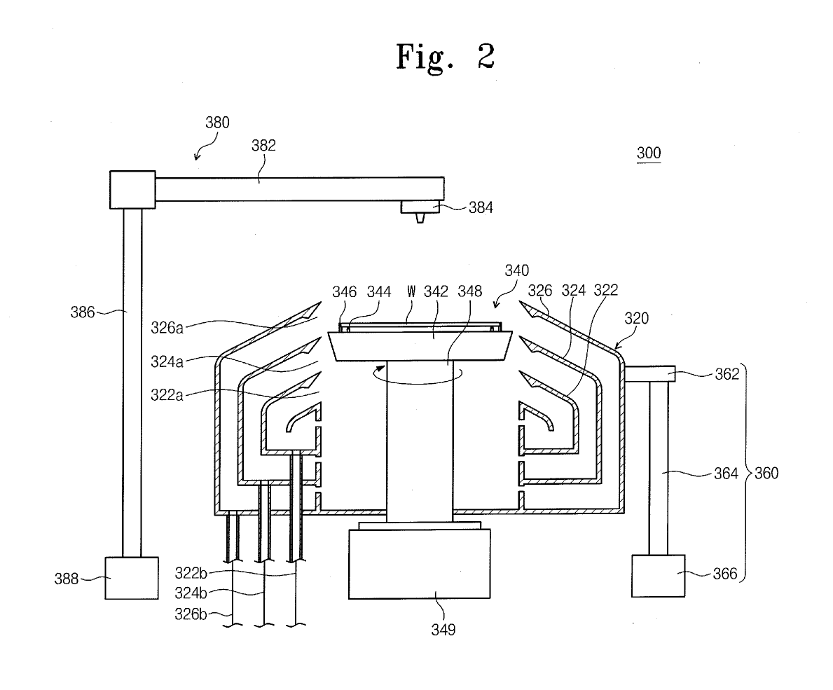

FIG. 2 is a cross-sectional view illustrating a substrate cleaning apparatus of FIG. 1 according to an embodiment.

FIG. 2 is a cross-sectional view schematically illustrating a substrate cleaning apparatus for cleaning a substrate in a first process chamber of FIG. 1. Referring to FIG. 2, a substrate cleaning apparatus 300 includes a container 320, a spin head 340, an elevation unit 360, and a spray unit 380. The container 320 provides a space in which a substrate cleaning process is performed and has an opened upper portion. The container 320 includes an internal recovery box 322, an intermediate recovery box 324, and an external recovery box 326. Each of the recovery boxes 322, 324, and 326 recovers the different treating solutions of the treating solutions used for the processes. The internal recovery box 322 has a circular ring shape surrounding the spin 340, the intermediate recovery box 324 has a circular ring shape surrounding the internal recovery box 322, and the external recovery box 326 has a circular ring shape surrounding the intermediate recovery box 324. An inner space 322a of the internal recovery box 322, a space 324a between the internal recovery box 322 and the intermediate recovery box 324, and a space 326a between the intermediate recovery box 324 and the external recovery box 326 may serve as inlets through which the treating solutions are respectively introduced into the internal recovery box 322, the intermediate recovery box 324, and the external recovery box 326, respectively. Recovery lines 322b, 324b, and 326b vertically extending downward from bottom surfaces of the recovery boxes 322, 324, and 326 are connected to the recovery boxes 322, 324, and 326, respectively. The treating solution introduced into each of the recovery boxes 322, 324, and 326 is discharged through each of the recovery lines 322b, 324b, and 326b. The discharged treating solution may be reused through an external treating solution recycling system (not shown).

The spin head 340 is disposed within the container 320. The spin head 340 supports and rotates a substrate W while a process is performed. The spin head 340 includes a main body 342, a support pin 334, a chucking pin 346, and a support shaft 348. The main body 342 has a top surface having a circular shape when viewed from an upper side. The support shaft 348 rotatable by a motor 349 is fixed and coupled to a bottom surface of the main body 342. The support pin 334 is provided in plurality. The support pins 334 are disposed on an edge of the top surface of the main body 342 and spaced apart from each other to protrude from the main body 342. The support pins 334 may be combined with each other to form a circular ring shape on the whole. The support pins 334 supports an edge of a back surface of the substrate W so that the substrate W is spaced a predetermined distance from the top surface of the main body 342. The chucking pin 346 is provided in plurality. The chucking pins 346 are disposed far away from a center of the main body 342 than the support pins 334. Each of the chucking pins 346 protrudes upward from the main body 342. The chucking pin 346 supports a lateral portion of the substrate W to prevent the substrate W from being separated laterally from a proper position of the substrate W when the spin heads 340 are rotated. The chucking pin 346 may be linearly movable between a standby position and a support position thereof along a radius direction of the main body 342. The standby position is a position far away from the center of the main body 342 than the support position. When the substrate W is loaded on or unloaded from the spin head 340, the chucking pin 346 is disposed at the standby position. Also, when the process is performed on the substrate W, the chucking pin 346 is disposed at the support position. The chucking pin 346 contacts the lateral portion of the substrate W at the support position.

The elevation unit 360 straightly moves the container 320 in a vertical direction. As the container 320 vertically moves, a relative height of the container 320 with respect to the spin head 340 may change. The elevation unit 360 includes a bracket 362, a moving shaft 364, and a driver 366. The bracket 362 is fixed to an outer wall of the container 320. The moving shaft 364 vertically moving by the driver 366 is fixedly coupled to the bracket 362. When the substrate W is placed on the spin head 340 or lifted from the spin head 340, the container 320 descends so that the spin head 340 protrudes upward from the container 320. Also, when the process is performed, the container 320 may be adjusted in height so that the treating solution is introduced into the preset recovery box 360 according to a kind of treating solution supplied onto the substrate W. For example, the substrate W is disposed at a height corresponding to the inner space 322a of the internal recovery box 322 while the substrate W is treated by using a first treating solution. Also, the substrate W may be disposed at a height corresponding to each of the space 324a between the internal recovery box 322 and the intermediate recovery box 324 and corresponding to the space 326a between the intermediate recovery box 324 and the external recovery box 326 while the substrate is treated by using each of a second treating solution and a third treating solution. Alternatively, the elevation unit 360 may vertically move the spin head 340 instead of the container 320.

The spray unit 380 supplies the treating solution onto the substrate W when the substrate cleaning process is performed. The spray unit 380 includes a nozzle support 382, a nozzle 384, a support shaft 386, and a driver 388. The support shaft 386 has a length direction parallel to the third direction 16. The driver 388 is coupled to a lower end of the support shaft 386. The driver 388 rotates and elevates the support shaft 386. The nozzle support 382 is vertically coupled to a side opposite to an end of the support shaft 386 coupled to the driver 388. The nozzle 384 is disposed on a bottom surface of an end of the nozzle support 382. The nozzle 384 moves between a process position and a standby position by the driver 388. The process position represents a position at which the nozzle 384 is disposed directly above the container 320, and the standby position represents a position at which the nozzle 384 is deviated from the direct upper side of the container 320. The spray unit 380 may be provided in one or plurality. When the spray unit 380 is provided in plurality, a chemical, a rinsing solution, a coating solution and an organic solvent may be provided through the spray units 380 different from each other, respectively. The chemical may be an etching solution, and the rinsing solution may be pure water. The organic solvent may be a mixture of isopropyl alcohol and an inert gas or an isopropyl alcohol solution. Also, the coating solution may be a water-soluble coating solution containing a siloxane-based hydrophobic compound reacting with silicon (Si) forming a pattern surface on the substrate. Alternately, the coating solution may be an organic coating solution in which a siloxane-based hydrophobic compound reacting with the Si forming the pattern surface on the substrate is contained in an organic solvent.

A substrate treating method for using the substrate treatment apparatus of FIG. 1 will be described below. The substrate treating method according to an embodiment of the present invention is not limited to the method using the substrate treatment apparatus of FIG. 1. That is, the substrate treatment apparatus of FIG. 1 is exemplified to explain the embodiment of the present invention. Thus, the substrate treating method of the present invention may be applied to various apparatus in addition to the substrate treating apparatus of FIG. 1.

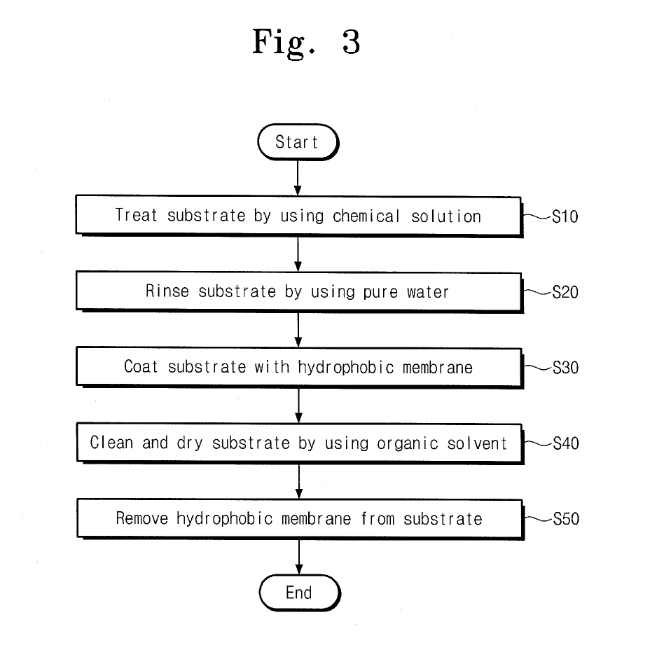

FIG. 3 is a flowchart illustrating a substrate treating method by using the substrate treating apparatus of FIG. 1.

Referring to FIG. 3, a substrate treating method includes a process (S10) of treating a substrate by using a chemical solution, a process (S20) of rinsing the substrate by using pure water, a process (S30) of coating the substrate with a hydrophobic membrane, a process (S40) of supplying an organic solvent to dry the substrate, and a process (S50) of removing the hydrophobic membrane from the substrate.

Hereinafter, the processes (S30 to S50) of coating a pattern of the substrate with the hydrophobic membrane and drying the substrate to prevent the pattern on the substrate from leaning will be described.

In a typical substrate treating method, a substrate was hydrophobized by treating a surface of the substrate by using a chemical solution to prevent a pattern on the substrate from leaning. In spite of this process, when the surface of the substrate is formed of an unhydrophobized material such as oxide or the like, or when a chemical solution such as SCl or the like that hydrophilzes the hydrophobic substrate is used, the pattern of substrate may be leaned. Also, as the pattern of the substrate gradually decreases in size, the leaning phenomenon of the pattern on the substrate may occur in a cleaning process in which an organic solution is used on the pattern of the substrate having the hydrophilic property.

According to an embodiment of the present invention, to prevent the leaning phenomenon of the pattern on the substrate from occurring, the process (S30) of coating a pattern surface of the substrate with a hydrophobic membrane is performed. If the main component of the coating solution for coating the substrate is water-soluble, the pattern on the substrate may be coated with the hydrophobic membrane by using the coating solution without supplying an organic solution after the process (S20) of rinsing the pure water. Here, if the coating solution is water-soluble, most siloxane-based hydrophobic chemical solutions may be used.

If the coating solution for the coating is provided on the substrate, a siloxane-base hydrophobic polymer contained in the coating solution may react with the Si forming the pattern surface on the substrate. Through these processes, the surface of the pattern on the substrate may be coated with the hydrophobic membrane.

After the substrate is coated with the hydrophobic membrane, the process (S40) of drying and cleaning the substrate by using an organic solvent is performed. After the process of coating the substrate with the hydrophobic membrane, the coating solution remaining without reacting with the surface of the pattern on the substrate may exist on the substrate. To clean the remaining coating solution, the organic solvent may be supplied on the substrate to clean the coating solution. Here, isopropyl alcohol may be provided as the organic solution. The organic solvent may be substituted by the coating solution remaining on the substrate to remove the coating solution from the substrate. The organic solvent may be substituted by pure water remaining after the rinsing process in addition to the coating solution to dry the substrate. In addition to the method using the organic solvent in the drying process, an inert gas (for example, N₂ gas) may be introduced into the process chamber while the substrate rotates to dry the substrate.

The process (S50) of removing the hydrophobic membrane coated on the substrate may be performed after the substrate is cleaned and dried. A rapid thermal processing (RTPC) process using plasma may be used as the process of removing the hydrophobic membrane. If a chemical solution is used to remove the hydrophobic membrane coated on the substrate, a leaning phenomenon may occur on the pattern on the substrate by pure water. An organic substance generated by removing the hydrophobic membrane may be removed in the RTPC process. Here, oxygen may be introduced into the process chamber to burn and remove the organic substance. The process (S50) of removing the hydrophobic membrane may be moved to a separate process chamber different from the chambers for performing the process (S30) of coating the substrate with the hydrophobic membrane and the process (S40) of cleaning and drying the substrate. Alternately, the process of coating the substrate with the hydrophobic membrane and the process of removing the hydrophobic membrane may be performed within the same chamber.

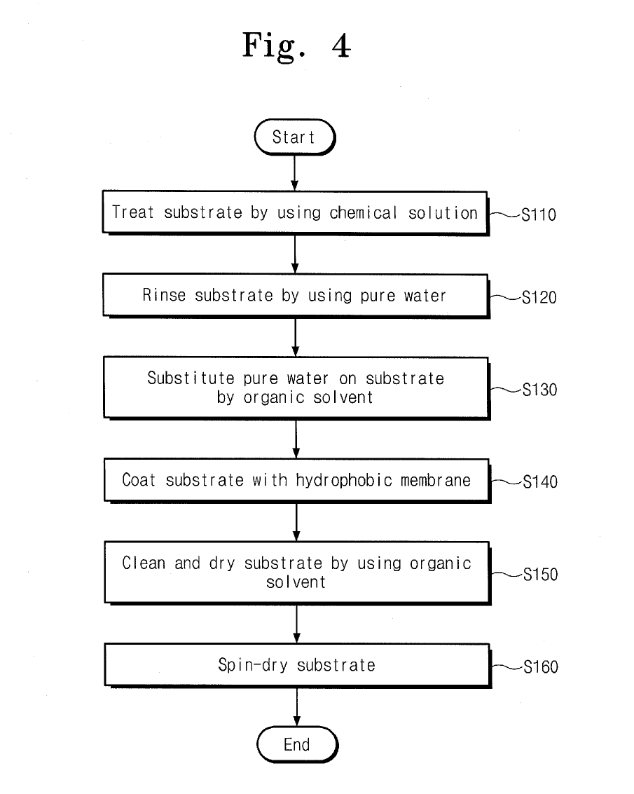

FIG. 4 is a flowchart illustrating a substrate treating method by using the substrate treating apparatus of FIG. 1.

Referring to FIG. 4, a substrate treating method includes a process (S110) of treating a substrate by using a chemical solution, a process (S120) of rinsing the substrate by using pure water, a process (S130) of substituting the pure water on the substrate by an organic solvent, a process (S140) of coating the substrate with the hydrophobic membrane, a process (S150) of treating the substrate by using the organic solvent, and a process (S160) of spin-drying the substrate.

Here, the substrate treating method is characterized in that the process (S120) of rinsing the substrate by using the pure water is performed, and then, the process (S130) of substituting the pure water by the organic solvent is performed before the substrate is coated with the hydrophobic membrane. Since the coating solution coating the substrate with the hydrophobic membrane includes an organic coating solution in which siloxane-based hydrophobic compound is mixed with the organic solution, the coating solution may not be well mixed with the pure water (that is used in the process of rinsing). However, since the organic coating solution and the organic solvent are the same organic-based material, the organic coating solution and the organic solvent may be easily substituted and reacted therebetween. Thus, when the pure water remaining on the substrate is substituted by the organic solvent, the coating solution may easily react with the pattern on the substrate. Therefore, the process of coating the surface of the pattern on the substrate with the hydrophobic membrane may be improved in efficiency. Here, isopropyl alcohol may be provided as the organic solvent.

The process (S150) of treating the substrate by using the organic solvent is performed after the substrate is coated with the hydrophobic membrane. After treating the substrate by using the coating solution for coating the substrate with the hydrophobic membrane, the remaining coating solution may exist on the substrate. To clean the remaining coating solution, the organic solvent may be supplied onto the substrate. Here, the isopropyl alcohol may be provided as the organic solvent. The organic solvent may be substituted by the coating solution remaining on the substrate to remove the coating solution from the substrate. Also, the organic solvent may be substituted by the pure water remaining after the rinsing process to dry the substrate. In addition to the method using the organic solvent in the drying process, an inert gas may be introduced into the process chamber while the substrate rotates to dry the substrate.

According to the present invention, the substrate treating method may be improved in the drying efficiency.

According to an embodiment of the present invention, the leaning phenomenon occurred on the pattern on the substrate may be prevented in the substrate treating process.

The object of the present invention is not limited to the aforesaid, but other objects not described herein will be clearly understood by those skilled in the art from descriptions below and accompanying drawings.

The foregoing detailed descriptions may be merely an example of the prevent invention. Also, the present invention is explained by describing the preferred embodiments and will be used through various combinations, modifications and environments. That is the present invention may be amended or modified, not being out of the scope, technical idea or knowledge in the art. Further, it is not intended that the scope of this application be limited to these specific embodiments or to their specific features or benefits. Rather, it is intended that the scope of this application be limited solely to the claims which now follow and to their equivalents.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A substrate treating method comprising:
treating a substrate by using a chemical solution;
rinsing the substrate by using pure water after treating the substrate by using the chemical solution; and
treating the substrate by using an organic solvent,
wherein the substrate treating method further comprises coating the substrate with a hydrophobic membrane between the treating of the chemical solution and the treating of the organic solvent.

2. The substrate treating method of claim 1, wherein the coating of the substrate with the hydrophobic membrane is performed after the rinsing of the substrate.

3. The substrate treating method of claim 2, further comprising supplying the organic solvent onto the substrate to substitute the pure water on the substrate by the organic solvent between the rinsing of the substrate and the coating of the substrate with the hydrophobic membrane.

4. The substrate treating method of claim 2, wherein the organic solvent comprises isopropyl alcohol (IPA).

5. The substrate treating method of claim 1, wherein the coating of the substrate with the hydrophobic membrane comprises providing a water-soluble coating solution containing a siloxane-based hydrophobic compound, which reacts with silicon (Si) on a surface of a pattern on the substrate, onto the substrate.

6. The substrate treating method of claim 1, wherein the coating of the substrate with the hydrophobic membrane comprises providing an organic coating solution in which a siloxane-based hydrophobic compound reacting with silicon (Si) on the surface of the pattern on the substrate is mixed with the organic solvent onto the substrate.

7. The substrate treating method of claim 1, further comprising removing the hydrophobic membrane after drying the substrate.
